(19) United States
(12) Patent Application Publication
(10) Pub. No.: US 2023/0389386 A1
(43) Pub. Date: Nov. 30, 2023

(54) FILTER FOR MICRO LED DISPLAY

(71) Applicant: Plessey Semiconductors Ltd, Plymouth Devon (GB)

(72) Inventors: Samir Mezouari, Plymouth Devon (GB); Geoff Dumas, Plymouth Devon (GB); James Pilkington, Plymouth Devon (GB); Colin Evestaff, Plymouth Devon (GB)

(21) Appl. No.: 18/030,821

(22) PCT Filed: Nov. 8, 2021
(86) PCT No.: PCT/GB2021/052888

§ 371 Date: Apr. 7, 2023

(30) Foreign Application Priority Data
Nov. 13, 2020 (GB) 2017942.0

(51) Int. Cl. H10K 59/38; H10K 71/15; H10K 59/80

(52) U.S. Cl. CPC H10K 59/38; H10K 71/15; H10K 59/878; H10K 2101/70

(57) ABSTRACT

A method of forming a light emitting diode array comprising a plurality of light emitting pixels, wherein at least one of the light emitting pixels comprises: a light emitting diode configured to emit light of a first primary peak wavelength; a first region comprising a first down conversion material configured to receive and convert input light of the first primary peak wavelength from the light emitting diode to provide output light of a second primary peak wavelength and unconverted light of the first primary peak wavelength; and a second region comprising organic semiconductor material dispersed in a medium, the organic semiconductor material configured to absorb input light of the first primary peak wavelength, wherein the second region is configured to transmit output light of the second primary peak wavelength from the first region and absorb unconverted light of the first primary peak wavelength passing from the light emitting diode through the second region, thereby to increase the light colour purity emitted by the at least one light emitting pixel.

### FIELD OF THE INVENTION

The invention relates to arrays of light emitting pixels and methods of forming arrays of light emitting pixels. In particular, but not exclusively, the invention relates to arrays of multicolour light emitting devices with improved colour purity and methods of forming arrays of multicolour light emitting devices with improved colour purity.

### BACKGROUND OF THE INVENTION

It is known that light emitting diode (LED) devices provide efficient sources of light for a wide range of applications. Increases in LED light generation efficiency and extraction, along with the production of smaller LEDs (with smaller light emitting surface areas) and the integration of different wavelength LED emitters into arrays, has resulted in the provision of high quality colour arrays with multiple applications, in particular in display technologies.

It is known that high-efficiency light emitting diodes can be formed from group III-V compound semiconductor structures. For example, highly efficient blue light emitting LED devices can be formed from nitride based materials. Since such efficient LEDs can be formed from such material, in some cases it can be particularly advantageous to use blue light LEDs to pump down-converting materials to provide different wavelengths of light, for example for use in multicolour displays, rather than sourcing LEDs emitting different wavelengths of light.

However, as the pixel pitch in such arrays is reduced to very small pitches (e.g., less than 5 μm) in order to provide higher resolution arrays, a number of difficulties arise. For example, quantum dots (QDs) are typically used as colour conversion layers to achieve a full colour red-green-blue (RGB) display, where blue LEDs are typically used as the source of input light. Such QDs are typically used to convert blue input light to red light and green light using appropriate QDs. However, such QD layers are generally required to be of the order of 20 μm to 30 μm thick in order to achieve full colour saturation. Therefore, at these thicknesses, the minimum pixel that can be produced is restricted to a width of above 20 μm.

Further difficulties are known to arise in processing QDs for light wavelength colour conversion in micro LED arrays, such as degradation in efficiency and lifetime of the wavelength converting QDs when forming layers of material comprising QDs using photolithography and inkjet printing, for example. Accordingly, there are significant challenges in the pursuit of high resolution micro LED arrays, for which it would be beneficial to have a pixel pitch is less than 10 μm.

### SUMMARY OF THE INVENTION

In order to mitigate for at least some of the above-described problems, there is provided a method of forming a light emitting diode array comprising a plurality of light emitting pixels, wherein at least one of the light emitting pixels comprises: a light emitting diode configured to emit light of a first primary peak wavelength; a first region comprising a first down conversion material configured to receive and convert input light of the first primary peak wavelength from the light emitting diode to provide output light of a second primary peak wavelength and unconverted light of the first primary peak wavelength; and a second region comprising organic semiconductor material dispersed in a medium, the organic semiconductor material configured to absorb input light of the first primary peak wavelength, wherein the second region is configured to transmit output light of the second primary peak wavelength from the first region and absorb unconverted light of the first primary peak wavelength passing from the light emitting diode through the second region, thereby to increase the light colour purity emitted by the at least one light emitting pixel.

There is also provided a light emitting diode array formed in accordance with the method.

Advantageously, organic semiconductor material dispersed in a medium can be processed using known semiconductor fabrication techniques to provide a thin layer that selectively filters unconverted light in colour converted LED arrays. Beneficially, thinner layers of colour conversion material can be used as the organic semiconductor material dispersed in a medium increases the colour purity (reduces or removes selected wavelengths) so that colour saturation using thicker layers of colour conversion material can be addressed.

Preferably, the method comprises forming at least one further light emitting pixel, wherein the at least one further light emitting pixel comprises: a further light emitting diode configured to emit light of the first primary peak wavelength; and a third region comprising a second down conversion material configured to receive and convert input light of the first primary peak wavelength from the further light emitting diode to output light of a third primary peak wavelength and unconverted light of the first primary peak wavelength, wherein the second region is configured to transmit output light of the third primary peak wavelength from the third region and absorb unconverted light of the first primary peak wavelength passing from the further light emitting diode through the third region, thereby to increase the light colour purity emitted by the at least one further light emitting pixel. Advantageously, the method provides multicolour arrays of light emitting pixels with higher colour purities in an effective and scalable manner, whereby the same organic semiconductor material dispersed in a medium is used to absorb unconverted light from colour conversion materials emitting different wavelengths of light.

Preferably, the second region is configured to absorb light at a wavelength associated with curing the medium in which the organic semiconductor material is dispersed. Advantageously, the second region is photodefinable, enabling improved processing whilst enhancing colour output purity from a light emitting array.

Preferably, the method comprises depositing the second region on a light emitting diode array, preferably wherein depositing the second region comprises slit coating or spin coating the medium and/or further medium. Advantageously, the second region is deposited in an efficient and scalable manner and can be integrated into semiconductor fabrication process flows.

Preferably, the method comprises selectively covering one or more light emitting diodes in the light emitting diode array with a material prior to depositing the second region, thereby to enable selective deposition of the second region. Advantageously, the second region is used selectively to filter wavelengths in a multicolour light emitting array.

Preferably, the material is at least one of: a temporary material that is removable thereby to enable further deposition of further material on the selectively covered one or more light emitting diodes in a further distinct step after deposition of the second region on the light emitting diode array; and an optically transparent material that enables light emission from the selectively covered one or more light emitting diodes, wherein the one or more light emitting diodes are configured to emit light with the primary peak wavelength. Advantageously, selected light emitting diodes are unaltered in their wavelength output.

Preferably, the medium comprises at least one of a resin and a polymer medium. Advantageously, such media enable processing multicolour arrays in an effective manner to improve colour purity.

Preferably, the method comprises forming a passivation layer on the light emitting diode array, thereby to protect light emitting diode array. Advantageously, the passivation layer protects the underlying layers whilst enabling light emission at particular wavelengths associated with different colour light emitting pixels.

Preferably, the organic semiconductors comprise conjugated organic semiconductors having a plurality of conjugated structures, preferably wherein the plurality of conjugated structures comprises a core and an arm, yet more preferably wherein at least two of the plurality of conjugated structures have a different functional property. Advantageously, such structures are tunable to provide absorption properties whilst being integrated in semiconductor fabrication techniques.

Preferably the organic semiconductors are deposited in a solvent, typically an organic solvent such as an alkene or alkane or mixtures thereof, preferably wherein the concentration of organic semiconductors in the solvent is 1 to 5%, more typically 2.5% by weight and more preferably wherein the solvent comprises toluene and heptane.

Preferably, one functional property is absorption at the first primary peak wavelength and/or wherein one functional property is absorption of light with a primary peak wavelength that enables curing of the medium. Advantageously, absorption of the first primary peak wavelength reduced the amount of unconverted light emitted from a colour conversion region and the absorption at a primary peak wavelength that enables curing of the medium provides an effective manner to process an improved colour purity array.

Preferably, the light emitting diode array is a high resolution monolithic micro LED array, preferably wherein the method comprises forming a reflective layer between at least two of the light emitting diodes in the high resolution monolithic micro LED array, more preferably wherein the high resolution monolithic LED has a pixel pitch less than 10 μm, preferably less than 4 μm. Advantageously, high resolution, high efficiency arrays emitting at a particular wavelength can be used to provide multicolour arrays by light wavelength conversion materials whilst reducing the amount of unconverted light. From the high resolution monolithic micro LED array.

Preferably, the plurality of light emitting pixels each have a light emitting surface that is less than or equal to 100 μm², preferably less than 16 μm². Advantageously, such arrays enable high resolution multicolour light emitting displays.

Preferably, the second region is a layer, preferably wherein the layer has a thickness less than 2 microns, more preferably wherein the layer has a thickness less than 0.5 microns. Advantageously, thin layers of colour conversion material enable smaller light emitting pixels and hence improved resolution displays.

Further aspects of the invention will be apparent from the description and the appended claims.

### DETAILED DESCRIPTION OF AN EMBODIMENT OF THE INVENTION

A detailed description of embodiments of the invention is described, by way of example only, with reference to the figures, in which:

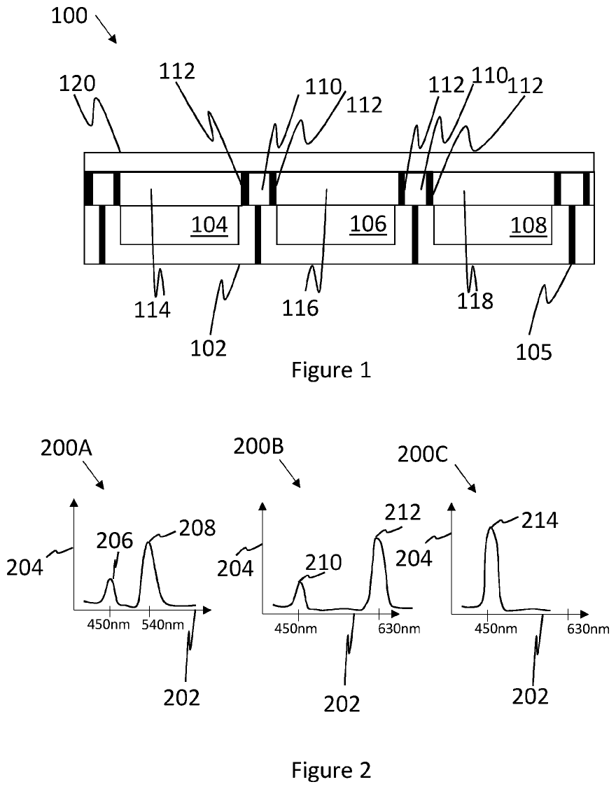

FIG. 1 shows a cross-sectional view of multicolour light emitting array;

FIG. 2 shows light spectra corresponding to different portions of the multicolour light emitting array of FIG. 1;

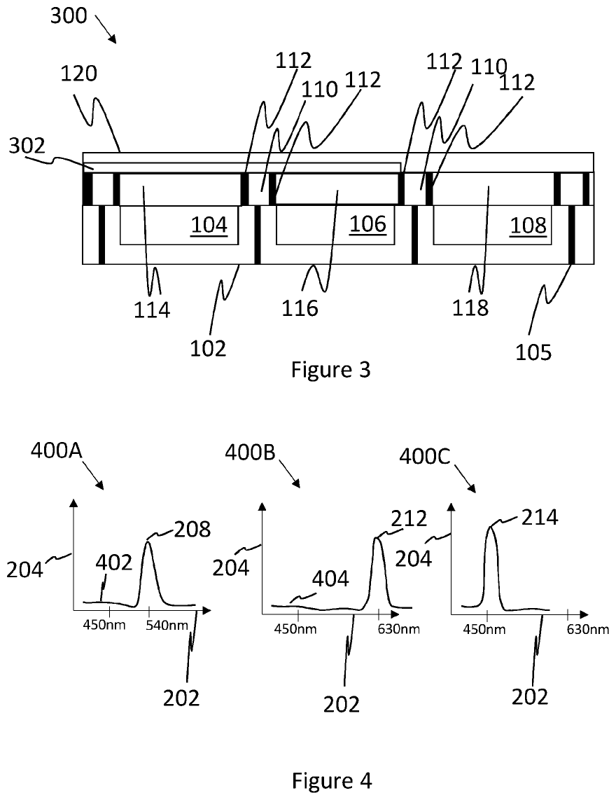

FIG. 3 shows a cross-sectional view of multicolour light emitting array;

FIG. 4 shows light spectra corresponding to different portions of the multicolour light emitting array of FIG. 3;

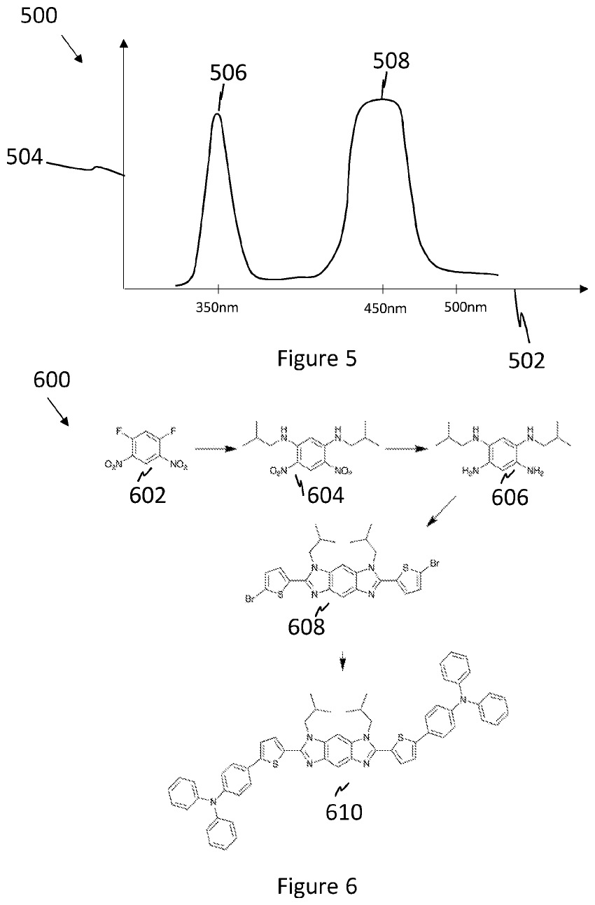

FIG. 5 shows the absorption characteristics of an organic semiconductor macromolecule region; and

FIG. 6 shows a sequence of steps to provide an organic semiconductor material.

Advantageously, a method of providing full colour saturation with very thin films is described. For example, monolithic light emitting diode (LED) arrays with LED devices emitting a primary peak wavelength can selectively be colourised using colour-conversion regions that absorb light with the primary peak wavelength and emit light with a different primary peak wavelength in order to provide multicolour light emitting arrays. For example, a monolithic array of LED devices emitting light with a primary wavelength corresponding to blue light (approximately 450 nm) can be selectively down converted to provide light emission with primary peak wavelengths corresponding to green light (approximately 540 nm) and/or red light (approximately 630 nm).

Where the thickness of the colour conversion regions is reduced to provide full colour saturation with thin films, there are associated benefits. For example, such thin films enable the use of thinner down-conversion regions with reduced absorption and therefore increased light emission compared with known techniques. Further, advantageously, the use of thinner films enables smaller light emitting pixels to be provided, thereby facilitating 35 high resolution light emitting arrays, such as high resolution micro LED arrays. Beneficially, the method is integrated within standard semiconductor processing techniques, meaning that multicolour arrays of light emitting devices can be produced in an economically efficient manner and on a large scale.

The colour conversion materials described herein are materials that can be used to down-convert light with one shorter (higher energy) wavelength to provide light of a longer (lower energy) wavelength. For example, blue or UV light can be down-converted by absorption and emission by colour conversion material to provide light with green and/or red wavelengths. Advantageously, colour conversion material can be used to provide light emission at different wavelengths from an array of light emitting devices emitting at one wavelength (for example, a blue-light emitting array of LED devices), thereby taking advantage of known methods for producing high quality, efficient, light emitting arrays, for example using nitrides-based III-V epitaxial crystalline compound semiconductor structures. Colour conversion can be achieved using organic and inorganic materials. For example, inorganic quantum dot (QD) materials, such as compound semiconductor QD materials, can be used to provide colour conversion from light with a shorter wavelength to provide light emission at a relatively longer wavelength.

Colour conversion materials comprising a medium in which organic semiconductors are dispersed are also known to enable the down-conversion of shorter wavelengths of light to provide light with longer wavelengths. It is known that down-converting organic semiconductors can be tuned in order to achieve targeted physical properties. In particular, advantageously, organic semiconductors can achieve specific values for the ionisation potential or electronic affinity, absorption and emission characteristics, charged transport properties, phase behaviour, solubility, and processability. Typically, organic semiconductors are conjugated organic semiconductors comprising a plurality of conjugated structures. In an example, such conjugated structures include a core and arm. The functionality of these constituent parts of the organic semiconductor are tuned in order to provide particular characteristics.

Macromolecules are discussed in Acc. Chem. Res 2019, 52, 1665 to 1674 and J. Mater. Chem. C, 2016, 4, 11499, for example, the contents of which are incorporated in their entirety. Macromolecules that are tunable include conjugated organic semiconductor comprising a plurality of conjugated structures. These are typically organic semiconductors. Such structures are formable to comprise a core and an arm. The plurality of conjugated structures can be formed to have a different functional properties, for example, different absorption and/or emission characteristics. In an example, organic semiconductor material providing colour conversion functionality is a synthesised TPA-BDI (triphenylamine-benzodiimidazole) molecular species, which is a benzodiimidazole-cored organic system. Such materials can be prepared from commercially available starting materials. Benzodiimidazoles and their derivatives have tuneable optical properties by using push-pull donor-acceptor components. In an example, TPA-BDI in down-converting hybrid LED devices is incorporated into an optically transparent material, such as poly(urethane) resin, as host and encapsulant.

FIG. 6 shows a sequence 600 illustrating how, in an example, TPA-BDI is synthesised in four steps from 1,5-difluoro-2,4-dinitrobenzene, shown as a first compound 602 in FIG. 6. There is shown an SNAr reaction of the first compound 602 with isobutylamine to provide a second compound 604 in high yield (for example, 90%). Subsequent reduction of the nitro groups of the second compound 604 provides a third compound 606 and condensation of the third compound with 5-bromo-2-thiophenecarboxaldehyde provides the key intermediate fourth compound 608 in approximately 47% yield over two steps. The final material TPA-BDI 610 is obtained through Suzuki-Miyaura cross-coupling of the fourth compound 608 with 4-(diphenylamino)phenylboronic acid pinacol ester in moderate yield (for example, 55%), thereby to provide TPA-BDI 610. Whilst the organic semiconductor material is Benzodiimidazoles and their derivatives in an example, in further examples, alternative and/or additional organic semiconductor materials providing light conversion functionality is used in the colour conversion region described herein. Beneficially, such macromolecules, including organic semiconductor material, can be tuned to absorb particular wavelengths of light, whilst remaining transparent to different wavelengths of light. Advantageously, such materials can be used to provide absorption at multiple, distinct, wavelengths. Further, as described below, the use of organic semiconductor material dispersed in a photo-definable medium enables efficient and effective processing of materials for the colourisation of arrays of light emitting devices, such as monolithic micro LED arrays.

FIG. 1 shows a cross-sectional view of multicolour light emitting array 100. There is shown a monolithic array of light emitting diode (LED) devices 104, 106, 108 configured to emit light with a primary peak wavelength that corresponds to blue light. The LED devices 104, 106, 108 are formed on a layer 102. The layer 102 is a gallium nitride (GaN) layer. Whilst the LED devices 104, 106, 108 are shown to be encased by the layer 102, the skilled person understands that the configuration of the LED devices 104, 106, 108 with respect to the layer 102 is configured in any appropriate manner. The individual LED devices 104, 106, 108 are shown to be separated by material 105 between each of the devices 104, 106, 108. The material 105 is configured to prevent optical cross talk between pixels. In further examples, additional and/or alternative layers and materials are used. In further examples, the material 105 is not used. Each of the LED devices 104, 106, 108 has a colour conversion region associated with it. The first LED device 104 is associated with a first colour conversion region 114. The second LED device 106 is associated with a second colour conversion region 116. The third LED device 108 is associated with a region 118 that does not convert light emitted by the corresponding third LED device 108. The region 118 associated with the third LED device 108 is substantially transparent to blue light. Accordingly, the region 118 defines a light emitting surface associated with a pixel that emits light with a primary peak wavelength corresponding to blue light. The use of the region 118 associated with the third LED device 108 provides a uniform planar layer in combination with the first colour conversion region 114 and the second colour conversion region 116. The region 118 associated with the third LED device 108 is an optically transparent resin. In further examples, alternative and/or additional materials forms the region 118 associated with the third LED device 108 such that input light from the third LED device 108 passes through the region 118 and is emitted from the light emitting array 100 structure.

The first colour conversion region 114 is configured to absorb light with a primary peak wavelength corresponding to blue light from the first LED device 104 and down convert the light in order to emit light with a primary peak wavelength corresponding to green light. Accordingly, the colour conversion region 114 defines a light emitting surface associated with a pixel that emits light with a primary peak wavelength corresponding to green light.

The second colour conversion region 116 is configured to absorb light with a primary peak wavelength corresponding to blue light from the first LED device 106 and down convert the light in order to emit light with a primary peak wavelength corresponding to red light. Accordingly, the colour conversion region 116 defines a light emitting surface associated with a pixel that emits light with a primary peak wavelength corresponding to red light.

The colour conversions regions are separated by regions 110 with additional reflective regions 112 to enable the formation of distinct pixels. In an example, the regions 110 are formed from a dielectric material and the reflective regions 112 are formed from metal that are, beneficially, formed by patterning and depositing appropriate materials before the formation of the colour conversion regions. In further examples, alternative and/or additional materials and/or techniques are used. In further examples, the additional reflective regions 112 are replaced with light absorbing regions better to define pixels.

The LED devices 104, 106, 108 and their corresponding regions 114, 116, 118 provide a multicolour light emitting array. On top of the regions 114, 116, 118 there is shown a passivation layer 120. The LED devices 104, 106, 108 are nitride-based, epitaxially grown, compound crystalline semiconductor LEDs 104, 106, 108. In further examples, other LEDs are used, such as other group III-V, or group II-VI based compound semiconductor materials. Advantageously, the LED devices 104, 106, 108 are grown monolithically, thereby to provide high quality material with excellent uniformity and efficiency, without a requirement to transfer individual LED devices. Beneficially, the monolithic LED array is coupled to a backplane (not shown) in order to enable control of individual LED devices 104, 106, 108 in the monolithic array. The LED devices 104, 106, 108 are grown as part of a monolithic array of LEDs using metal organic chemical vapour deposition (MOCVD). In further examples, alternative and/or additional techniques are used to form the LED devices 104, 106, 108 as part of a monolithic array, such as molecular beam epitaxy (MBE) and other suitable deposition/growth techniques. In further examples, other additional and/or alternative semiconductor fabrication and processing techniques are used to provide the monolithic array of LED devices 104, 108, 108. In further examples, alternatively and/or additionally, the array 100 is formed from individual LED devices that do not form part of a monolithic array.

The three LED devices 104, 106, 108 are shown without electrical connections that facilitate the injection of carriers via p-type and n-type regions in order to provide emissive recombination and the skilled person understands that such electrical connections for injection of carriers by the p-type and n-type regions in a LED device may be implemented in different ways. For example, the array 100 can be coupled with a complementary metal oxide semiconductor (CMOS) backplane to control emission from individual LED devices.

Whilst the LED devices 104, 106, 108 are illustrated in a particular configuration in the array 100, the skilled person understands that alternative and/or additional configurations and implementations of LED devices may be used in combination with the further features described herein. Whilst only three LED devices 104, 106, 108 are shown in cross section, in further examples any appropriate number of LED devices is used to form an array 100.

FIG. 2 shows light emission spectra corresponding to different portions of the multicolour light emitting array of FIG. 1.

The first spectrum 200A shows a plot of light intensity on the vertical scale 204 versus wavelength on the horizontal scale 202. There are two significant peaks, the first peak 206 of which corresponds to blue light and the second peak 208 of which corresponds to green light. The blue light of the first peak 206 is light from the first LED device 104 that has not been down converted by the colour conversion region 114 and the green light of the second peak 208 is light from the first LED device 104 that has been down converted by the colour conversion region 114.

The second spectrum 200B shows a plot of light intensity on the vertical scale 204 versus wavelength on the horizontal scale 202. There are two significant peaks, the first peak 210 of which corresponds to blue light and the second peak 212 of which corresponds to red light. The blue light of the first peak 210 is light from the second LED device 106 that has not been down converted by the colour conversion region 116 and the red light of the second peak 212 is light from the second LED device 106 that has been down converted by the colour conversion region 116.

The third spectrum 200C shows a plot of light intensity on the vertical scale 204 versus wavelength on the horizontal scale 202. There is one significant peak, the peak 214 corresponds to blue light. The blue light of the peak 214 is light from the third LED device 108 that has passed through the region 118.

In order to reduce the intensity of the peaks 206, 210 relating to unconverted blue light in green and red pixels, the thickness of the colour conversion region 114, 116, associated with them can be increased. However, such increases in thickness increase the absorption of light in the colour conversion region that leads to a reduction in intensity of the output (converted) light. Further, thicker colour conversion regions generally inhibit the production of smaller light emitting pixels used in high resolution displays.

FIG. 3 shows a cross-sectional view of multicolour light emitting array 300. The multicolour light emitting array 300 corresponds to the multicolour light emitting array 100 of FIG. 1 with an additional layer 302 formed on the colour conversion regions 114, 116 associated with the first and second LED devices 104, 106. The additional layer 302 provides a region that is configured to absorb light at selected wavelengths, thereby to improve the light output of a multicolour light emitting array 300.

The additional layer 302 comprises organic semiconductor material dispersed in a resin and configured to absorb blue light. The additional layer 302 is formed by patterning and forming the additional layer 302 on regions associated with the first and second LED devices 104, 106 of the multicolour light emitting array 100 of FIG. 1 prior to forming a passivation layer. The multicolour light emitting array 100 is patterned using known semiconductor fabrication techniques, such as photolithography, selectively to cover portions where the additional layer 302 is not to be formed. The additional layer 302 is formed using spin coating or slit coating. In further examples, different methods and/or materials are used in order to form the additional layer 302 at appropriate locations on the multicolour light emitting array 100, thereby to provide a blue light blocking layer to absorb unconverted light from the LEDs 104, 106 that are associated with pixels emitting light that has been converted at the associated colour conversion regions 114, 116.

The absorption properties of the additional layer 302 are shown at FIG. 5. FIG. 5 shows an absorption spectrum 500, where the vertical scale 504 relates to absorption and the horizontal scale 502 relates to wavelength. The additional layer 302 comprising organic semiconductor material is shown to have two distinct absorption peaks. The first absorption peak 506 relates to absorption of ultraviolet (UV) light at approximately 350 nm. The second peak 508 relates to absorption of blue light at approximately 450 nm. Away from these peaks, light is transmitted through the additional layer 302. For example, red and green light is transmitted through the additional layer 302. The first absorption peak 506 relates to the resin in which the organic semiconductor material is dispersed. In further examples, the organic semiconductor material is configured to absorb light at the first absorption peak 506, thereby enhancing UV absorption by the additional layer 302 and enabling improved processing of the photo-definable additional layer 302. In an example, the organic semiconductor material providing targeted absorption functionality is a synthesised TPA-BDI molecular species, which is a benzodiimidazole-cored organic system. Such materials can be prepared from commercially available starting materials. Benzodiimidazoles and their derivatives have tuneable optical properties by using push-pull donor-acceptor components. In an example, TPA-BDI is incorporated into an optically transparent poly(urethane) resin as host and encapsulant. In further examples, a different medium is used as host and encapsulant for the TPA-BDI. The organic semiconductors are deposited in a solvent, typically an organic solvent such as an alkene or alkane or mixtures thereof, preferably wherein the concentration of organic semiconductors in the solvent is 1 to 5%, more typically 2.5% by weight and more preferably wherein the solvent comprises toluene and heptane

FIG. 6 shows how, in an example, TPA-BDI is synthesised in four steps from 1,5-difluoro-2,4-dinitrobenzene, shown as a first compound 502 in FIG. 6. There is shown an SNAr reaction of the first compound 502 with isobutylamine to provide a second compound 504 in high yield (for example, 90%). Subsequent reduction of the nitro groups of the second compound 504 provides a third compound 506 and condensation of the third compound with 5-bromo-2-thiophenecarboxaldehyde provides the key intermediate fourth compound 508 in approximately 47% yield over two steps. The final material TPA-BDI 510 is obtained through Suzuki-Miyaura cross-coupling of the fourth compound 508 with 4-(diphenylamino)phenylboronic acid pinacol ester in moderate yield (for example, 55%), thereby to provide TPA-BDI 510. Whilst the organic semiconductor material is Benzodiimidazoles and their derivatives in an example, in further examples, alternative and/or additional organic semiconductor materials providing light conversion functionality is used in the colour conversion region. In a further example, the organic semiconductor macromolecule is based on 4,4-difluoro-4-bora-3a,4a-diaza-s-indacene (BODIPY), for example the macromolecule comprises a BODIPY core. In yet further examples, the macromolecule is based on a 2,1,3-benzothiadiazole (BT) core.

Whilst the additional layer 302 is described as region configured to absorb light with a primary peak wavelength corresponding to blue light and ultraviolet light, in further examples the additional layer 302 is a region that is configured selectively to absorb light with different wavelengths of light, for example, green light. Absorbing different wavelengths of light corresponding to input light from an array of light emitting devices that use the input light for colour conversion regions to provide converted light output provides increased colour purity for the colour converted light from thin films of tunable organic semiconductors dispersed in a definable medium by reducing or removing one or more unwanted wavelengths of light emitted from the array.

FIG. 4 shows light spectra corresponding to different portions of the multicolour light emitting array 300 of FIG. 3.

The first spectrum 400A shows a plot of light intensity on the vertical scale 204 versus wavelength on the horizontal scale 202. There is one significant peak, which corresponds to the second peak 208, corresponding to green light, as described with reference to FIG. 2. The blue light of the first peak 206 seen in FIG. 2 has been supressed and there is an insignificant peak 402 corresponding to light from the first LED device 104 that has not been down converted by the colour conversion region 114.

The second spectrum 400B shows a plot of light intensity on the vertical scale 204 versus wavelength on the horizontal scale 202. There is one significant peak, which corresponds to the second peak 212, corresponding to red light, as described with reference to FIG. 2. The blue light of the first peak 206 seen in FIG. 2 has been supressed and there is an insignificant peak 404 corresponding to light from the second LED device 106 that has not been down converted by the colour conversion region 114.

The third spectrum 400C shows a plot of light intensity on the vertical scale 204 versus wavelength on the horizontal scale 202. There is one significant peak, the peak 214 corresponds to blue light. The blue light of the peak 214 is light from the third LED device 108 that has passed through the region 118.

Accordingly, the use of a blue filter layer enhances the colour purity of the two light emitting surfaces associated with the non-blue light of the first and second colour conversion regions 114, 116 that down convert light from the first and second LED devices 104, 106 by reducing or removing one or more unwanted wavelengths of light emitted from the array. Insignificant peaks relate to the absence or near absence of light emitted at a corresponding wavelength. For example, the measured light intensity emitted is less than a threshold. The threshold can be related to an acceptable colour purity of the light emitted by a pixel, for example with respect to the intensity of the primary peak output (e.g., red light for a red light emitting pixel, green light for a green light emitting pixel).

Advantageously, the use of the additional layer 302 acting as a blue absorbing colour filter means that the first and second colour conversion regions 114, 118 can be thinner than typically used to achieve full colour saturation with an appropriate colour purity (e.g., an appropriate level of one or more unwanted wavelengths that have been reduced in intensity and/or removed). Typically for micro-LED displays with a pitch less than 5 microns, in order to provide an acceptable down-conversion efficiency of input light, the ratio of the thickness of the colour conversion region to the size of the emitting area is if the order of 1:4. For short pitch arrays, where the LED pitch is a square 3 microns, the light emitting area is of the order of 2 square microns. Accordingly, ideally the thickness of the down-conversion region is of the order of 0.4 microns. Typically, where such thin layers of colour conversion material (such as quantum dots) are used, a reasonable amount of the input pump light is unconverted and therefore good colour saturation is not ordinarily achieved. The use of the additional layer 302 means that full colour saturation can be achieved with colour conversion regions of the order of 0.5 microns where the colour conversion region comprises organic semiconductor material and of the order of 2 microns when the colour conversion region comprises quantum dots. Therefore, the combination of organic semiconductors in a medium (such as TPA-BDI in resin tuned to absorb unconverted light) with a colour conversion region (such as one formed from TPA-BDI in resin tuned to down convert light) reduces the overall required thickness of the region to provide a particular colour purity of light output. Accordingly, shorter pitch arrays with a higher density of LED devices converting high quality input light, such as light from monolithic blue light emitting nitrides based arrays is enabled. Beneficially, known techniques can be used to provide highly efficient, high resolution, arrays of light emitting devices, for example by the epitaxial growth of compound semiconductor materials, that are subsequently processed to provide light at different wavelengths, without compromising on the colour purity of the light output by the individual pixels.

What is claimed is:

1. A method of forming a light emitting diode array comprising a plurality of light emitting pixels, wherein at least one of the light emitting pixels comprises:
a light emitting diode configured to emit light of a first primary peak wavelength;
a first region comprising a first down conversion material configured to receive and convert input light of the first primary peak wavelength from the light emitting diode to provide output light of a second primary peak wavelength and unconverted light of the first primary peak wavelength; and
a second region comprising organic semiconductor material dispersed in a medium, the organic semiconductor material configured to absorb input light of the first primary peak wavelength, wherein the second region is configured to transmit output light of the second primary peak wavelength from the first region and absorb unconverted light of the first primary peak wavelength passing from the light emitting diode through the second region, thereby to increase the light color purity emitted by the at least one light emitting pixel.

2. The method according to claim 1, comprising forming at least one further light emitting pixel, wherein the at least one further light emitting pixel comprises:
a further light emitting diode configured to emit light of the first primary peak wavelength; and
a third region comprising a second down conversion material configured to receive and convert input light of the first primary peak wavelength from the further light emitting diode to output light of a third primary peak wavelength and unconverted light of the first primary peak wavelength, wherein the second region is configured to transmit output light of the third primary peak wavelength from the third region and absorb unconverted light of the first primary peak wavelength passing from the further light emitting diode through the third region, thereby to increase the light color purity emitted by the at least one further light emitting pixel.

3. The method according to claim 1, wherein the second region is configured to absorb light at a wavelength associated with curing the medium in which the organic semiconductor material is dispersed.

4. The method according to claim 1, comprising depositing the second region on a light emitting diode array, and depositing the second region comprises at least one of slit coating and spin coating the medium.

5. The method according to claim 4, comprising selectively covering one or more light emitting diodes in the light emitting diode array with a material prior to depositing the second region, thereby to enable selective deposition of the second region.

6. The method according to claim 5, wherein the material is at least one of:
a temporary material that is removable thereby to enable further deposition of further material on the selectively covered one or more light emitting diodes in a further distinct step after deposition of the second region on the light emitting diode array; and
an optically transparent material that enables light emission from the selectively covered one or more light emitting diodes, wherein the one or more light emitting diodes are configured to emit light with the primary peak wavelength.

7. The method according to claim 1, wherein the medium comprises at least one of a resin and a polymer medium.

8. The method according to claim 1, comprising forming a passivation layer on the light emitting diode array, thereby to protect light emitting diode array.

9. The method according to claim 1, wherein the organic semiconductors comprise conjugated organic semiconductors having a plurality of conjugated structures, and the plurality of conjugated structures comprises a core and an arm, and wherein at least two of the plurality of conjugated structures have a different functional property.

10. The method according to claim 9, wherein a functional property is one of absorption at the first primary peak wavelength and absorption of light with a primary peak wavelength that enables curing of the medium.

11. The method according to claim 1, wherein the light emitting diode array is a high resolution monolithic micro LED array, and wherein the method comprises forming a reflective layer between at least two of the light emitting diodes in the high resolution monolithic micro LED array.

12. The method according to claim 11 wherein the high resolution monolithic LED has a pixel pitch less than 10 μm.

13. The method according to claim 12 wherein the high resolution monolithic LED has a pitch less than 4 μm.

14. The method according to claim 1, wherein the plurality of light emitting pixels each have a light emitting surface that is less than or equal to 100 μm².

15. The method according to claim 14, wherein the plurality of light emitting pixels each have a light emitting surface that is less than 16 μm².

16. The method according to claim 1, wherein the second region is a layer.

17. The method according to claim 13, wherein the layer has a thickness less than 2 microns.

18. The method according to claim 14 wherein the layer has a thickness less than 0.5 microns.

19. A light emitting diode array formed in accordance with the method of claim 1.
